(19) United States
(12) Patent Application Publication
(10) Pub. No.: US 2014/0291148 A1
(43) Pub. Date: Oct. 2, 2014

(54) SPUTTERING APPARATUS

(71) Applicant: CANON ANELVA CORPORATION, Kanagawa-ken (JP)

(72) Inventors: Toru ISHIMURA, Machida-shi (JP); Yasushi YASUMATSU, Inagi-shi (JP); Naoyuki OKAMOTO, Tama-shi (JP)

(21) Appl. No.: 14/304,129

(22) Filed: Jun. 13, 2014

Related U.S. Application Data
(63) Continuation of application No. PCT/JP2012/006144, filed on Sep. 26, 2012.

(30) Foreign Application Priority Data
Dec. 16, 2011 (JP) 2011-275490

(51) Int. Cl. H01J 37/34

(52) U.S. Cl. CPC H01J 37/3405
USPC 204/298.16

(57) ABSTRACT

A sputtering apparatus includes a power application device configured to apply power to set a cathode body and a cathode magnet to an equipotential. The power to be applied to the cathode magnet is supplied via a spline arranged between the cathode body and a magnet rotating shaft attached to the cathode magnet.

This application is a continuation of International Patent Application No. PCT/JP2012/006144 filed on Sep. 26, 2012, and claims priority to Japanese Patent Application No. 2011-275490 filed on Dec. 16, 2011, the entire content of both of which is incorporated herein by reference.

### BACKGROUND OF THE INVENTION

1. Field of the Invention

The present invention relates to a sputtering apparatus and, more particularly, to a sputtering apparatus capable of adjusting the distance between a target and a magnet.

2. Description of the Related Art

In a cathode that changes the distance between a target and a magnet to control a deposition process, when introducing a high frequency, the magnet and the cathode body are preferably set to an equipotential to prevent abnormal discharge between the members.

In a sputtering apparatus (for example, PTL 1) capable of adjusting the distance (TM distance) between a target and a cathode magnet, the magnet and the cathode (body) are electrically connected via a flexible thin plate (copper plate) and thus set to an equipotential.

PTL 1: Japanese Patent Laid-Open No. 2001-081554

### SUMMARY OF THE INVENTION

However, in a structure in which the thin plate moves every time the magnet moves, an insulating space (space) to arrange the thin plate is necessary. In addition, the repetitive motion of the thin plate may loosen screws that fasten it. Furthermore, since a change in the electrical resistance caused by a change in the shape of the copper plate may lead to a change in the power supply state and a variation in the electrical resistance, the copper plate needs to be exchanged periodically.

The present invention has been made in consideration of the above problem, and provides an electrically stable sputtering apparatus that is easy to maintain and capable of changing the distance between a target and a magnet.

According to the present invention, there is provided a sputtering apparatus comprising a cathode body on which a target can be arranged, a cathode magnet configured to generate a magnetic field on a surface of the target arranged on the cathode body, a magnet driving device configured to rotate the cathode magnet and move the cathode magnet close to or away from the cathode body, and a power application device configured to apply power to set the cathode body and the cathode magnet to an equipotential, wherein the magnet driving device includes a magnet support portion connected to the cathode magnet, and a slide support unit configured to support the magnet support portion to be movable in a direction to move close to or away from the cathode body, and the power application device supplies the power to the cathode magnet via the slide support unit.

Since power is supplied to the magnet and the cathode body via a spline, a sputtering apparatus that is reliable and easy to maintain can be provided.

Other features and advantages of the present invention will be apparent from the following descriptions taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a schematic view showing a sputtering apparatus according to the first embodiment of the present invention;

FIG. 2A is a sectional view taken along a line A-A in FIG. 1;

FIG. 2B is a sectional view taken along a line B-B in FIG. 1;

FIG. 3 is a schematic view showing a sputtering apparatus according to the second embodiment of the present invention;

FIG. 4 is an enlarged view of a spline shaft portion in FIG. 4;

FIG. 5 is a schematic view showing a sputtering apparatus according to the third embodiment of the present invention; and

FIG. 6 is an enlarged view of a spline shaft portion in FIG. 6.

### DESCRIPTION OF THE EMBODIMENTS

Embodiments of the present invention will now be described with reference to the accompanying drawings. It should be noted that members, arrangements, and the like to be described below are merely specific examples of the present invention and are not intended to limit the scope of the present invention, and various changes and modifications can be made within the spirit and scope of the present invention, as a matter of course.

### First Embodiment

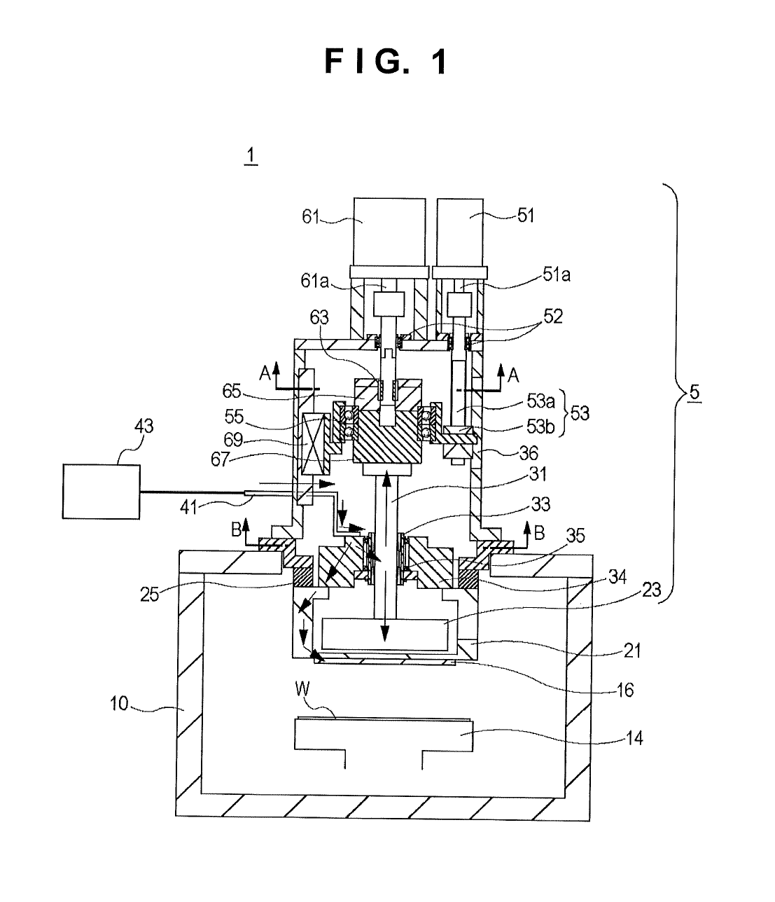

A sputtering apparatus according to the first embodiment of the present invention will be described with reference to FIGS. 1 to 3. A sputtering apparatus 1 shown FIG. 1 is formed by attaching a cathode device 5 to a vacuum container 10 that can be evacuated. A substrate holder 14 capable of holding a substrate W is arranged in the vacuum container 10. A target 16 attached to the cathode device 5 faces the substrate W held by the substrate holder 14. The target 16 is attached to a cathode body 21. A cathode magnet 23 that generates a magnetic field (magnetic force) on the surface of the target 16 is arranged on the other side of the cathode body 21.

The cathode body 21 can function as a vacuum partition and attach the target 16 to a position facing the substrate holder 14. The cathode device 5 can adjust the vertical position of the cathode magnet 23 with respect to the cathode body 21 provided on the vacuum container 10 via an insulator 25. Note that the magnet 23 includes a yoke attached to a magnet rotating shaft 31 (magnet support portion), and a permanent magnet provided on the target side of the yoke. A lower housing 34 is one of the members of the cathode body 21.

The arrangement of the cathode device 5 will be described. The cathode device 5 includes a magnet driving device that moves the cathode magnet 23 in the vertical direction (direction to move close to or away from the target 16) while rotating the cathode magnet 23, and a power application device that supplies power to the cathode magnet 23 and the cathode body 21 and applies an equipotential to them.

The magnet driving device includes the magnet rotating shaft 31 that supports the cathode magnet 23, a spline 33 that supports the magnet rotating shaft 31 to be vertically movable (movable) with respect to the cathode body 21, a bearing 35 that supports the magnet rotating shaft 31 to be rotatable with respect to the cathode body 21, a motor 51 that moves the magnet rotating shaft 31 in the vertical direction, and a motor 61 that rotates the magnet rotating shaft 31. The spline 33 (slide support unit) is attached to the cathode body 21 (lower housing 34). Both the motors 51 and 61 are attached to the side of the vacuum container 10 via a frame 36.

The rotating force of the motor 51 is transmitted to the magnet 23 via an output shaft 51a, a ball screw 53, an upper housing 65, an insulator 67, and the magnet rotating shaft 31, and vertically moves the magnet 23 in the cathode body 21. A screw shaft 53a and a female screw 53b of the ball screw 53 are connected to the output shaft 51a and the upper housing 65, respectively, and the upper housing 65 vertically moves in accordance with the rotation of the motor 51. Since the upper housing 65 is attached to the female screw 53b via a bearing 55, the upper housing 65, the insulator 67, and the magnet rotating shaft 31 can rotate the cathode magnet 23 independently of the arrangement of the ball screw 53. In addition, a linear guide 69 is attached between the upper housing 65 and the frame 36 and regulates the movements of the upper housing 65 in directions other than the vertical direction.

The rotating force of the motor 61 is transmitted to the cathode magnet 23 via an output shaft 61a, an upper spline 63, the upper housing 65, the insulator 67, and the magnet rotating shaft 31, and rotates the cathode magnet 23 in the cathode body 21. That is, the upper housing 65, the insulator 67, and the magnet rotating shaft 31 are configured to vertically move while rotating. Note that the output shafts 51a and 61a are axially supported by bearings 52, respectively.

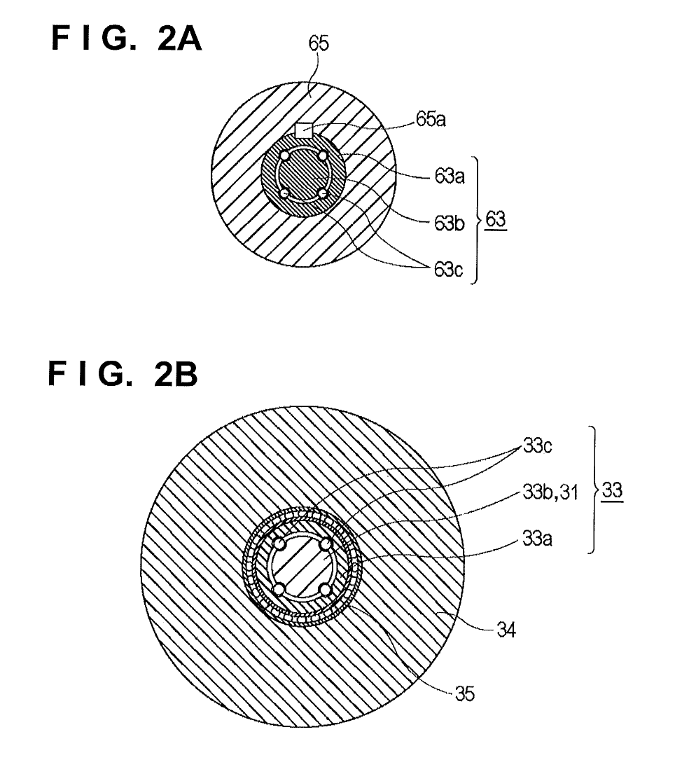

The spline 33 and the upper spline 63 will be described. FIGS. 2A and 2B are sectional views taken along a line A-A and a line B-B in FIG. 1, respectively. The sectional view taken along the line A-A shows the section of the portion of the upper spline 63, and the sectional view taken along the line B-B shows the section of the portion of the spline 33. The upper spline 63 shown in FIG. 2A is formed by fitting a spline shaft 63b in a spline nut 63a. Each of the inner surface of the spline nut 63a and the outer surface of the spline shaft 63b has grooves formed in the vertical direction. Spherical lock members 63c are arranged so as to be locked in the grooves of the spline nut 63a and the spline shaft 63b. Hence, in the upper spline 63, the spline shaft 63b can slide in the vertical direction with respect to the spline nut 63a while the rotating force is transmitted between the spline nut 63a and the spline shaft 63b via the lock members 63c.

The upper spline 63 is arranged between the upper housing 65 and the output shaft 61a. The spline nut 63a is connected to the upper housing 65, and the spline shaft 63b is connected to the output shaft 61a. A non-slip member 65a is arranged between the spline nut 63a and the upper housing 65 to prevent displacement. It is therefore possible to vertically move the upper housing 65 with respect to the output shaft 61a while transmitting the rotating force of the output shaft 61a to the upper housing 65.

The spline 33 shown in FIG. 2B has the same structure as the upper spline 63. The spline 33 is formed by fitting a spline shaft 33b in a spline nut 33a. Lock members 33c are arranged so as to be locked in the grooves of the spline nut 33a and the spline shaft 33b. Hence, in the spline 33, the spline shaft 33b can slide in the vertical direction with respect to the spline nut 33a while the rotating force is transmitted between the spline nut 33a and the spline shaft 33b. Note that since the spline shaft 33b according to this embodiment is integrated with the magnet rotating shaft 31, the spline shaft 33b and the magnet rotating shaft 31 will be described as the same member hereinafter.

The spline shaft 33b is integrated with the magnet rotating shaft 31, and the spline nut 33a is connected to the lower housing 34 via the bearing 35. The bearing 35 is arranged between the spline nut 33a and the lower housing 34 not to transmit the rotation of the spline nut 33a to the lower housing 34. It is therefore possible to vertically move the magnet rotating shaft 31 with respect to the lower housing 34 while rotating only the magnet rotating shaft 31.

The magnet rotating shaft 31, the spline 33, and the upper spline 63 are arranged while making their rotation axes match on one line. When they are arranged on one line, the cathode device 5 can have a compact structure.

The power application device will be described. The power application device (see FIG. 1) includes a power supply member 41 electrically connected to an external power supply 43. The power supply member 41 is connected to the conductive lower housing 34. The lower housing 34 is electrically connected to the magnet rotating shaft 31 and the cathode body 21 via the bearing 35 and the spline 33. All the spline nut 33a, the spline shaft 33b, and the lock members 33c included in the spline 33 are made of a conductive metal (for example, stainless steel), and satisfactory conductivity is ensured between the spline nut 33a and the spline shaft 33b. The bearing 35 also uses a material having satisfactory conductivity.

The magnet rotating shaft 31 is connected to the cathode magnet 23, and the target 16 is attached to the cathode body 21. For this reason, the lower housing 34, the cathode body 21, the target 16, the magnet rotating shaft 31, and the cathode magnet 23 are electrically connected to the power supply member 41 and set in the same electrical state (high voltage portion). Note that the power supply member 41 according to this embodiment is fixed to the lower housing 34 by screws. However, they need only be conductively connected, and therefore may be, for example, welded.

The vacuum container 10, the frame 36, and the driving components such as the motors 51 and 61 are set to the ground potential by the insulators 25 and 67. That is, the power supply member 41 can be connected to the cathode body 21 without contacting the vacuum container 10, the frame 36, and the like. The connection position between the power supply member 41 and the cathode body 21 is always fixed without any position variation caused by the operation (rotation and vertical movement) of the cathode magnet 23.

A voltage applied from the power supply member 41 is supplied to the side of the target 16 and the side of the cathode magnet 23 via the cathode body 21. That is, it is possible to supply power to the target side and the magnet side from one power supply portion of one power supply member 41. In addition, since the magnet rotating shaft 31 and one spline 33 only intervene from the lower housing 34 to which the power supply member 41 is connected to the cathode magnet 23, stable power supply to the cathode magnet 23 is possible. Note that the power supply path from the power supply member 41 is indicated by arrows in FIG. 1.

According to this embodiment, since it is possible to electrically reliably and stably supply power to the cathode magnet 23 via the spline 33 and set the target 16 and the cathode magnet 23 to an equipotential, stable plasma discharge can be implemented without fear of abnormal discharge. The magnet driving device is configured using the upper spline 63 not to vertically move the motor 61 serving as the rotation driving source of the cathode magnet 23. Hence, the motor 61 can be arranged not to vertically move.

### Second Embodiment

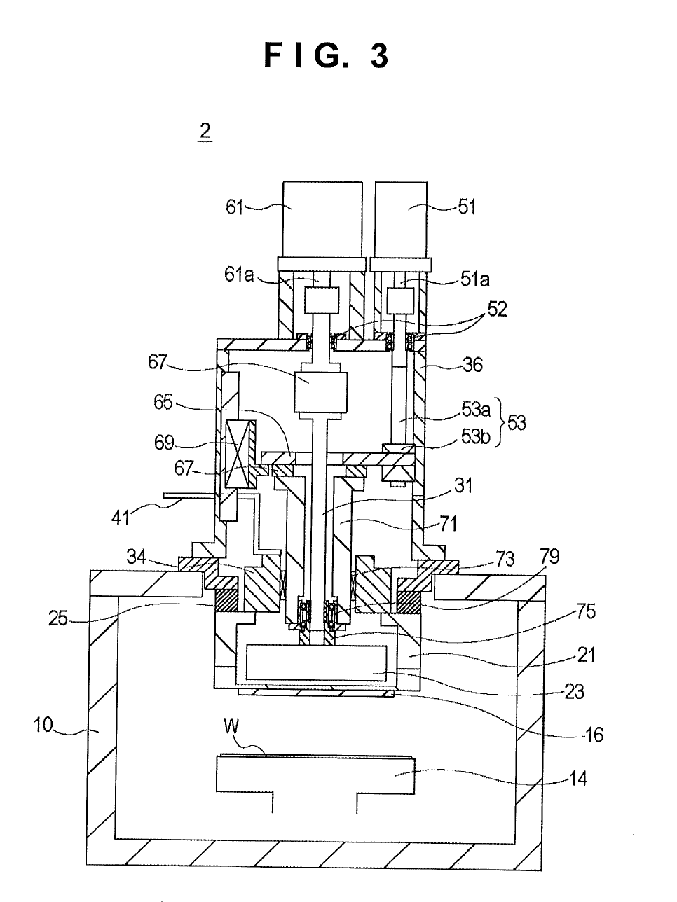

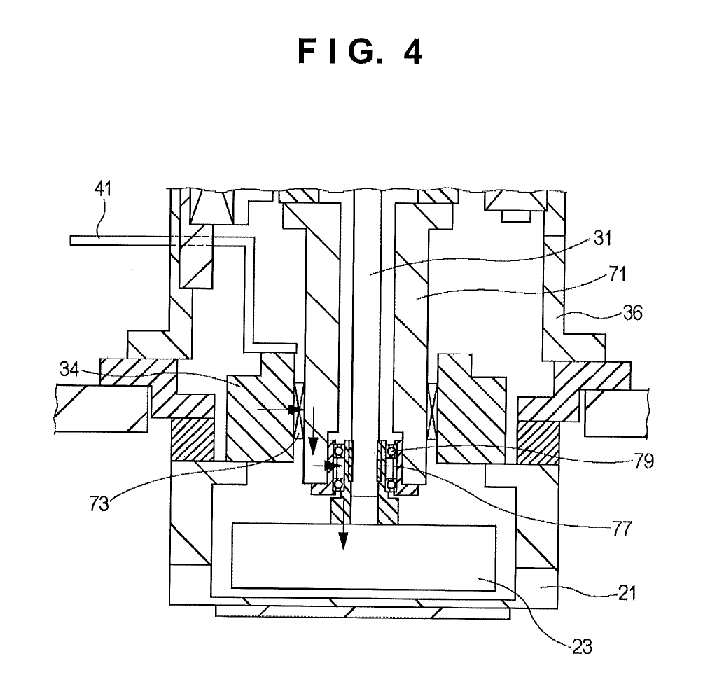

A sputtering apparatus 2 according to the second embodiment of the present invention will be described with reference to FIGS. 3 and 4. The same reference numerals as in the first embodiment denote the same members, arrangements, and the like, and a detailed description thereof will be omitted. The second embodiment is different from the first embodiment in the arrangement of the magnet driving device. More specifically, the sputtering apparatus is largely different in including a magnet rotating shaft 31, a moving member 71, and a magnet support shaft 75. The magnet rotating shaft 31 is a member that transmits the rotating force of a motor 61 to a cathode magnet 23 (magnet support shaft 75), and does not move vertically. Note that the magnet support portion according to this embodiment corresponds to the magnet rotating shaft 31, the moving member 71, and the magnet support shaft 75. The magnet driving device includes a spline 73 (outer spline) and a spline 77 (inner spline) as a slide support unit.

The moving member 71 is a tubular member provided on the outer surface side of the magnet rotating shaft 31. The moving member 71 vertically moves the cathode magnet 23 (magnet support shaft 75) as a ball screw 53 moves but does not rotate. The magnet support shaft 75 is a tubular member connected to the cathode magnet 23. The distal end of the magnet rotating shaft 31 is arranged in the magnet support shaft 75 via the spline 77 (inner spline). The magnet rotating shaft 31 is arranged to be coaxial with the magnet support shaft 75 and the moving member 71. That is, the spline 77 is arranged between the magnet support shaft 75 and the magnet rotating shaft 31. For this reason, the magnet support shaft 75 can vertically move while the rotating force is transmitted from the magnet rotating shaft 31 to the magnet support shaft 75.

A bearing 79 is arranged between the magnet rotating shaft 31 and the moving member 71. The bearing 79 rotatably supports the magnet support shaft 75 in the moving member 71. The magnet support shaft 75 vertically moves together with the bearing 79 and the moving member 71. The spline 73 is arranged between the moving member 71 and a lower housing 34 to prevent displacement in the vertical movement of the moving member 71. The spline 73 (outer spline) is a member that supports the moving member 71 to be slidable only in the vertical direction with respect to the lower housing 34. Note that since the moving member 71 is configured not to rotate, a slide bush may be used in place of the spline 73.

With the above arrangement, the sputtering apparatus 2 according to this embodiment has almost the same effects as the sputtering apparatus 1 according to the first embodiment. That is, since it is possible to electrically stably supply power to the cathode magnet 23 via the spline 73 and the bearing 79 and set a target 16 and the cathode magnet 23 to an equipotential, stable plasma discharge can be implemented without fear of abnormal discharge.

### Third Embodiment

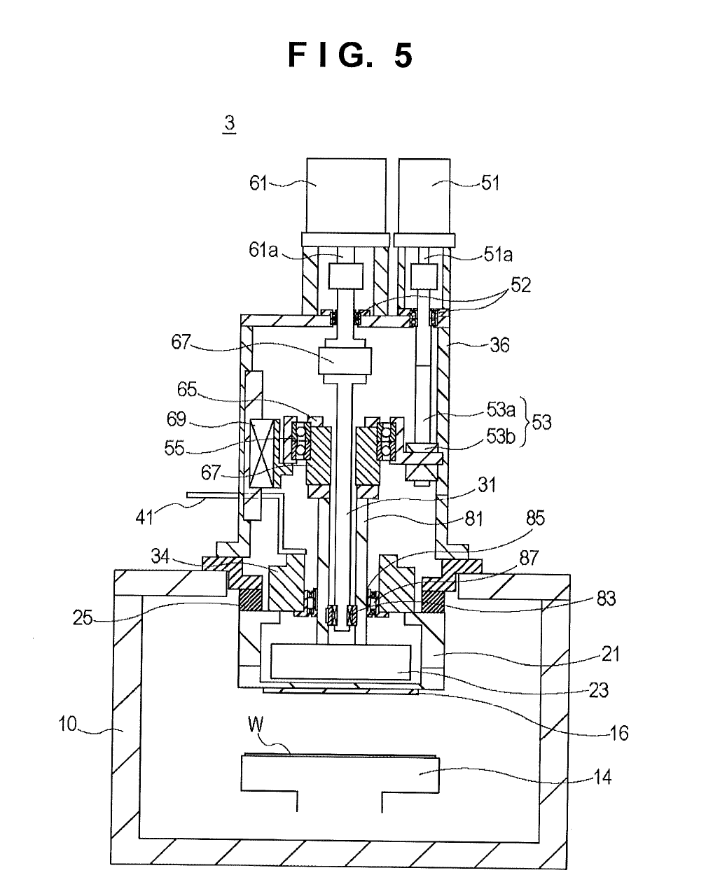

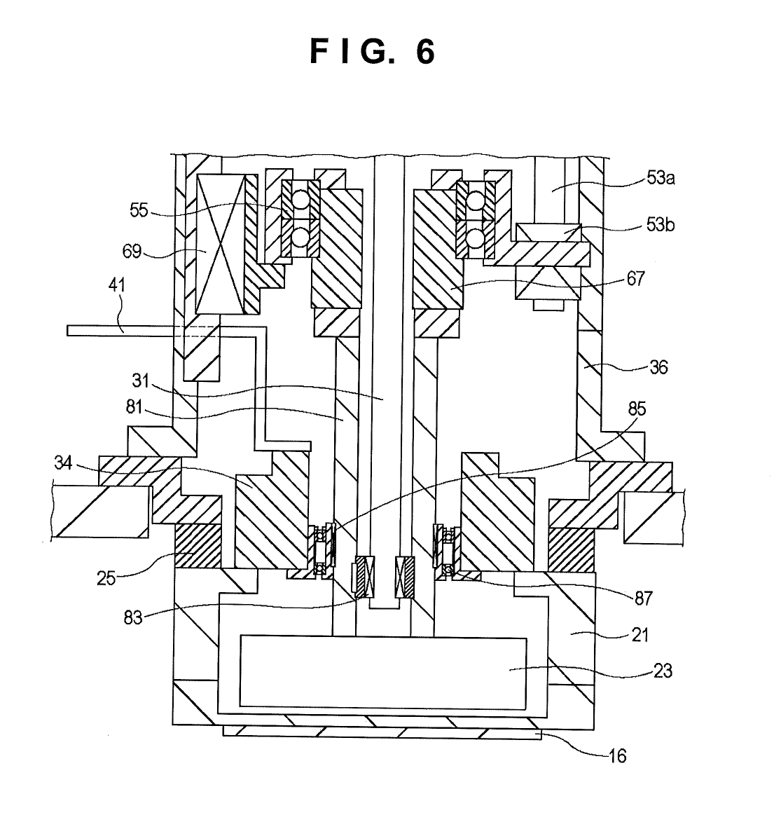

A sputtering apparatus 3 according to the second embodiment of the present invention will be described with reference to FIGS. 5 and 6. The same reference numerals as in the first embodiment denote the same members, arrangements, and the like, and a detailed description thereof will be omitted. This embodiment is different from the first embodiment in the arrangement of the magnet driving device. In the sputtering apparatus 3 according to this embodiment, the power supply line only passes through one rotary spline, as in the first embodiment. The sputtering apparatus includes a spline 83 (outer spline) and a spline 85 (inner spline) as a slide support unit.

More specifically, the sputtering apparatus is largely different in including a magnet rotating shaft 31 and a moving member 81. The magnet rotating shaft 31 is a member that transmits the rotating force of a motor 61 to a cathode magnet 23 (moving member 81), and does not move vertically. Note that the magnet support portion according to this embodiment corresponds to the magnet rotating shaft 31 and the moving member 81.

The moving member 81 is a tubular member provided on the outer surface side of the magnet rotating shaft 31. The moving member 81 vertically moves the cathode magnet 23 as a ball screw 53 moves, and also rotates as the magnet rotating shaft 31 rotates. The moving member 81 is connected to the cathode magnet 23. The magnet rotating shaft 31 is arranged to be coaxial with the moving member 81. The spline 83 (inner spline) is arranged between the magnet rotating shaft 31 and the moving member 81. The spline 85 (outer spline) and a bearing 87 are arranged between the moving member 81 and a lower housing 34. The spline 85 is arranged in contact with the moving member 81, and the bearing 87 is arranged in contact with the lower housing 34. For this reason, the moving member 81 can vertically move while rotating. Note that the spline 85 and the bearing 87 may be integrated (rotary spline).

With the above arrangement, the sputtering apparatus 3 according to this embodiment has almost the same effects as the sputtering apparatus 1 according to the first embodiment. That is, since it is possible to electrically stably supply power to the cathode magnet 23 via the spline 85 and the bearing 87 and set a target 16 and the cathode magnet 23 to an equipotential, stable plasma discharge can be implemented without fear of abnormal discharge.

The present invention is not limited to the above embodiment and various changes and modifications can be made within the spirit and scope of the present invention. Therefore, to apprise the public of the scope of the present invention, the following claims are made.

What is claimed is:

1. A sputtering apparatus comprising:
a cathode body on which a target can be arranged;
a cathode magnet configured to generate a magnetic field on a surface of the target arranged on said cathode body;
a magnet driving device configured to rotate said cathode magnet and move said cathode magnet close to or away from said cathode body; and
a power application device configured to apply power to set said cathode body and said cathode magnet to an equipotential,
wherein said magnet driving device includes a magnet support portion connected to said cathode magnet, and a slide support unit configured to support said magnet support portion to be movable in a direction to move close to or away from said cathode body, and
said power application device supplies the power to said cathode magnet via said slide support unit.

2. The sputtering apparatus according to claim 1, wherein said magnet support portion comprises a magnet rotating shaft configured to rotate together with said cathode magnet,
said magnet rotating shaft moves in the direction to move close to or away from said cathode body, and
said slide support unit is arranged between said cathode body and said magnet rotating shaft.

3. The sputtering apparatus according to claim 1, wherein said magnet support portion includes a magnet support shaft connected to said cathode magnet, a magnet rotating shaft configured to transmit a rotating force to said magnet support shaft, and a moving member connected to said magnet support shaft via a bearing and configured to move said magnet support shaft in the direction to move close to or away from said cathode body,
said slide support unit includes an outer spline arranged between said cathode body and said moving member, and an inner spline arranged between said magnet rotating shaft and said magnet support shaft, and
said power application device supplies the power to said cathode magnet via said outer spline and said inner spline.

4. The sputtering apparatus according to claim 3, wherein each of said magnet support shaft and said moving member comprises a tubular member, and
said magnet rotating shaft is arranged to be coaxial with said magnet support shaft and said moving member.

5. The sputtering apparatus according to claim 1, wherein said magnet support portion includes a moving member connected to said cathode magnet and configured to move in the direction to move close to or away from said cathode body, and a magnet rotating shaft configured to transmit a rotating force to said moving member,
said slide support unit includes an outer spline arranged between said cathode body and said moving member, and an inner spline arranged between said moving member and said magnet rotating shaft, and
said power application device supplies the power to said cathode magnet via said outer spline.

6. The sputtering apparatus according to claim 5, wherein said moving member comprises a tubular member, and
said magnet rotating shaft is arranged to be coaxial with said moving member.
